(19) United States
(12) Patent Application Publication
(10) Pub. No.: US 2015/0144188 A1
(43) Pub. Date: May 28, 2015

(54) BLACK GLASS AND SOLAR CELL ASSEMBLY USING THE SAME

(71) Applicant: CHANGZHOU ALMADEN CO., LTD., Changzhou (CN)

(72) Inventors: Jinxi Lin, Changzhou (CN); Jinhan Lin, Changzhou (CN); Ling Chen, Changzhou (CN); Guoxiang Wang, Changzhou (CN); Zhilong Ni, Changzhou (CN)

(73) Assignee: CHANGZHOU ALMADEN CO., LTD., Changzhou (CN)

(21) Appl. No.: 14/550,562

(22) Filed: Nov. 21, 2014

(30) Foreign Application Priority Data
Nov. 22, 2013 (CN) 201310596317.1

(51) Int. Cl. H01L 31/0216; H01L 31/048

(52) U.S. Cl. CPC H01L 31/02167; H01L 31/0488
USPC 136/256

(57) ABSTRACT

The subject invention is related to a black glass and a solar cell assembly comprising the same. The subject invention provides a black glass comprising a glass substrate; and a black coating formed on the glass substrate, wherein the black coating comprises an inorganic film-forming material, a black pigment and an adhesive. The subject invention also provides a solar cell assembly comprising: a front glass substrate; the aforementioned black glass; and a photovoltaic cell sealed between the front glass substrate and the black glass. The black glass of the subject invention has a good thermal conductivity, waterproof performance, mechanical properties and weather resistance such that the black glass is not only aesthetically pleasing but also useful as a backside protection material of a solar cell assembly for long-term outdoor use.

### BACKGROUND 1. Field of the Invention

The subject invention is related to a black glass, particularly a black glass having a good thermal conductivity, improved, or preferably excellent, waterproof performance, mechanical properties, weather resistance, and usability as a backside protection material for a solar cell assembly. 2. Description of the Related Art

Due to global warming and other environmental problems resulting from exploitation of fossil fuels and carbon dioxide emissions, there is urgent need in the industry to find clean and efficient alternative energy sources as a replacement for coal, or to ease the consumption of fossil fuels. Solar energy is found to be clean and environmentally friendly, and has become one of the promising alternative energy sources.

Generally, a solar cell assembly comprises a front glass to receive the sunlight upon exposure and protect the underlying solar cells, and a backside protection material to support the solar cells, wherein sealant such as ethylene vinyl acetate copolymer (EVA) may be used to hold or attach the front glass, the solar cells, and the backside protection material together.

For solar cell assemblies which are designed for long-term outdoor use, particularly for a period up to 20 years, weather resistance and waterproof performance of the front glass and the backside protection material used in the solar cell assemblies are crucial. Particularly, the mechanical properties of backside protection materials are important since backside protection materials are used to support the solar cells.

Current backside protection materials of solar cells are made of fluoride-containing polymers. However, such fluoride-containing materials have disadvantages such as undesirable weather resistance and waterproof performance, lower mechanical strength and high price. Attempts were made in the art to improve backside protection materials made of fluorine-containing materials. For example, a Chinese patent application, CN 102301492 A, discloses a blended resin including a fluorine-based resin and a (meth)acrylic-based copolymer resin to improve the weather resistance and waterproof performance of backside protection materials. However, there is still room for improvement on the anti-aging ability and mechanical strength of said backside protection materials.

Most backside protection materials made of fluoride-containing materials are white. CN 102177204 discloses a dark fluoride resin film prepared by adding black pigments such as carbon black into fluoride-containing backside protection materials so that the assembly has aesthetically pleasing appearance,

It is known that glass has excellent weather resistance and waterproof performance and is suitable for use as a backside protection material in solar cell assemblies in different environments, such as in a desert or on a beach. Further, glass has better thermal conducticity than fluoride-containing materials so that the heat generated during the operation of solar cells can be transferred from the solar cells. Therefore, it comes to the skilled person's attention that glass may be used as a backside protection material in a solar cell assembly and as a replacement of conventional fluoride-containing materials.

In light of the various applications of solar cell assemblies and in order to make the appearance of a solar cell assembly more appealing and pleasing to the public, and to fit into the surroundings where the solar cell assembly is set, glass which not only scientifically shows desirable properties for long-term outdoor use but also is aesthetically decorative to the surroundings is needed, and development of various glasses having different colors are desirable and should be developed.

Given the aforementioned problems left in the prior art, there is still a need to develop an improved backside protection material for use in solar cell assembly.

### SUMMARY

The subject invention provides a black glass with a good thermal conductivity, improved, or preferably excellent, waterproof performance, mechanical properties, and weather resistance, which not only shows an aesthetically pleasing appearance, but also meets the requirements for long-term outdoor use. Such black glass not only imparts a solar cell assembly comprising such black glass with outstanding appearance, allowing the appearance of the solar cell assembly to show a dark color, but also fulfills the need for developing a black solar cell assembly for long-term outdoor use.

The subject invention also provides a black glass which can be manufactured using simple techniques at low cost, and is suitable for mass production.

Specifically, the subject invention is directed to a black glass comprising: a glass substrate; and a black coating formed on the glass substrate, wherein the black coating comprises an inorganic film-forming material, a black pigment and an adhesive. The subject invention is also directed to a solar cell assembly comprising: a front glass substrate; the aforementioned black glass as the backside protection material; and a photovoltaic cell sealed between the front glass substrate and the aforementioned black glass.

### BRIEF DESCRIPTION OF THE DRAWINGS

FIG. 1 shows the structure of the black glass according to an embodiment of the subject invention.

FIG. 2 shows a solar cell assembly according to an embodiment of the subject invention.

It should be noted that elements in the drawing are not depicted according to the ratio of their actual sizes.

### DETAILED DESCRIPTION

In this context, unless otherwise limited, a singular term (such as “a”) also includes a plural form thereof. In this context, all embodiments and exemplary terms (for example, “such as”) are not intended to limit the scope of the present invention; terms in this specification should not be construed as implying that any component not claimed may form a necessary component for implementing the present invention.

Other than in any operating examples, or where otherwise indicated, all numbers expressing quantities of ingredients, reaction conditions and so forth used in the specification and claims are to be understood as being modified in all instances by the term “about.” Accordingly, unless indicated to the contrary, the numerical parameters set forth in the following specification and attached claims are approximations that may vary depending upon the desired properties to be obtained by the present invention. It should be understood that any numerical range recited herein is intended to include all sub-ranges and numbers subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10, such as 1.2 to 8.8 or 0.673 to 7.5952, and numbers, such as 5.61396 . . . or 8. At the very least, and not as an attempt to limit the application of the doctrine of equivalents to the scope of the claims, each numerical parameter should at least be construed in light of the number of reported significant digits and by applying ordinary rounding techniques.

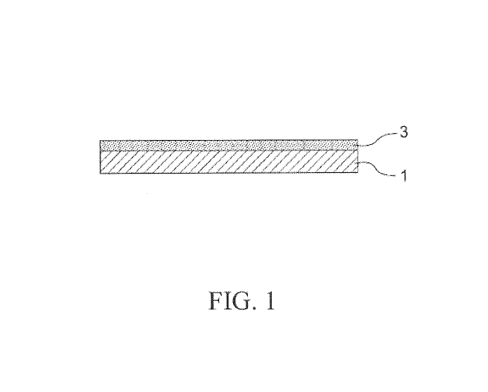

As shown in FIG. 1, according to one of the embodiments of the subject invention, the black glass of the subject invention comprises: a glass substrate 1; and a black coating 3 formed on the glass substrate, wherein the black coating comprises an inorganic film-forming material, a black pigment and an adhesive.

According to one of the embodiments of the subject invention, the glass substrate may be any suitable materials in the art including, but not limited to, a plate glass or a calendered glass.

According to one of the embodiments of the subject invention, the glass may be subjected to a tempered treatment, a half-tempered treatment, a tempered heat treatment, a half-tempered heat treatment, a physical tempered treatment or a half-physical tempered treatment; or not subjected to any of the foregoing treatments.

According to one of the embodiments of the subject invention, the glass substrate has a thickness of at least about 0.2 mm

According to one of the embodiments of the subject invention, the inorganic film-forming material may be any suitable materials in the art including, but not limited to, SiO₂, ZrO₂, BaSO₄, Al₂O₃, CaCO₃, CaSO₄, ZnO, Pb₃O₄, Sb₂O₃, TiO₂, MgO, MgCO₃, mica, lead white, talc or a combination thereof. The inorganic film-forming material has a particle size of about 0.001 μm to about 50 μm, preferably about 0.1 μm to about 5 μm, more preferably about 0.2 μm to about 3 μm.

Based on the total weight of the black coating, the inorganic film-forming material has a content of about 3% to about 40%, preferably about 4% to about 20%, more preferably about 10% to about 18%.

According to one of the embodiments of the subject invention, the black pigment may be any suitable organic or inorganic black pigments in the art including, but not limited to, carbon black, lamp black, acetylene black, channel black, gas black, thermal black, bone black, graphite, iron oxide black, nigrosin or a combination thereof.

The pigment has a particle size of about 0.001 μm to about 70 μm, preferably about 0.1 μm to about 10 μm, more preferably about 0.2 μm to about 5 μm.

According to one of the embodiments of the subject invention, based on the total weight of the black coating, the pigment has a content of about 0.2% to about 20%, preferably about 3% to about 17%, more preferably about 5% to about 15%.

According to one of the embodiments of the subject invention, the adhesives may be any suitable materials in the art including, but not limited to, colloids made from alcohol alcoholate (such as tetrabutyl titanate, tetraethyl orthosilicate or tetramethyl orthosilicate), organic salts (such as Pb(CH₃COO)₂), inorganic salts (such as Zn(NO₃)₂ and zirconium oxychloride) and/or organicmetallic compounds; organic polymers, for example, novolac resins, urea-formaldehyde resins, expoxy resins, polyvinyl acetate, polyvinyl acetate acetate, polyurethane, acrylate, polystyrenes, alkyd resins, polyisocyanate, diacrylate, silanes, polybenzimidazole, polyimide, butyl rubber, and tetrabutyl orthosilicate; and a combination thereof. By the total weight of the black coating, the content of the adhesives is from about 3% to about 40%, preferably from about 4% to about 20%, more preferably from about 10% to about 18%.

Optionally, the black coating of the subject invention may comprise one or more of the following additives: catalysts or auxiliaries. The auxiliaries may be items such as emulsifiers, dispersants, polymerization inhibitors, rheological agents, anti-settling agents, siccatives, anti-skinning agents, anti-shrinking agents, anti-impairment agents, anti-oxidation agents, lubricants, release agents, thermal stabilizers, light stabilizers, anti-electrostatic agents, abrasion resistants, thickening agents, defoamers or a combination thereof.

The content of the auxiliaries, if added, is from about 0.1% to about 20%, preferably from about 1% to about 18%, more preferably from about 5% to about 16% based on the total weight of the black coating.

In addition, the black coating of the subject invention may optionally comprise a solvent.

The aforementioned catalysts may be any suitable materials in the art including, but not limited to, inorganic acids, organic acids, bases, acidic salts, basic salts or organic ammonium salts or a combination thereof.

The content of the catalysts, if added, is from about 0.1% to about 1%, preferably from about 0.3% to about 0.8%, more preferably from about 0.4% to about 0.7% based on the total weight of the black coating.

The aforementioned solvents may be any suitable materials in the art including but not limited to, water, petroleum solvents, benzene solvents, terpene solvents, alcohol solvents, ether solvents, ketone solvents, ester solvents, chlorinated hydrocarbon solvents, nitro hydrocarbon solvents or amine solvents or a combination thereof.

The content of the solvents, if added, is from about 20% to about 70%, preferably from about 25% to about 65%, more preferably from about 35% to about 50% based on the total weight of the black coating.

According to one of the embodiments of the subject invention, the black glass of the subject invention is prepared by a process comprising: (1) providing a glass substrate; (2) coating a surface of the glass substrate with a black coating composition comprising an inorganic film-forming material, a black pigment and an adhesive; (3) curing the coated glass substrate.

According to one of the embodiments of the subject invention, the inorganic film-forming material, black pigment and adhesives are mixed at a specific ratio at a temperature of about 0° C. to about 60° C., preferably about 15° C. to about 50° C., more preferably about 25° C. to about 40° C., for a period from about 0.2 hour to about 48 hours, preferably for about 3 hours to 20 hours, more preferably for 5 hours to 10 hours (depending on the adopted temperature). In other words, the time period will vary depending on the temperature chosen, e.g., higher temperatures may require less time. When the mixture is homogeneously mixed, catalysts are added, and the mixing is carried out for about 0.2 hour to about 48 hours, preferably for about 5 hours to 25 hours, more preferably for 10 hours to 20 hours.

According to one of the embodiments of the subject invention, the black coating composition is applied onto the surface of the glass substrate by roll coating, spray coating, dip coating, slot coating, spin coating, printing, supersonic atomization or a combination thereof.

According to one of the embodiments of the present invention, the coated glass substrate is cured at a temperature from about 0° C. to about 800° C., preferably from about 150° C. to about 500° C., more preferably from about 200° C. to about 450° C. for a curing period from about 30 seconds to about 60 hours, preferably about 2 minutes to about 1 hour, more preferably about 3 minutes to about 0.5 hour (depending on the adopted curing temperature).

According to one of the embodiments of the subject invention, the black coating on the coated glass substrate has a thickness of about 0.2 μm to about 200 μm.

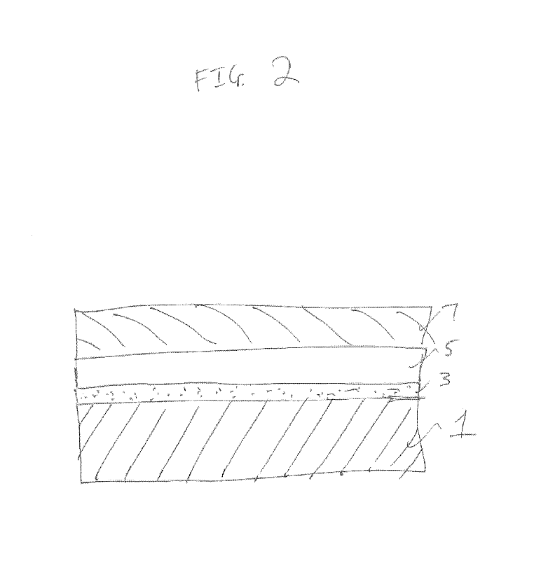

According to one of the embodiments of the subject invention, the solar cell assembly of the subject invention comprises: a front glass substrate; the aforementioned black glass; and a photovoltaic cell sealed between the front glass substrate and the black glass. In a preferred embodiment as illustrated in FIG. 2, the black glass 1, 3 may act as a backside coating glass. The photovoltaic cell 5 is sealed between the backside coating glass (1, 3) and the front glass substrate 7.

According to one of the embodiments of the subject invention, the solar cell assembly may comprise thermoplastic materials, such as but not limited to ethyl vinyl acetate (EVA), filled between the front glass substrate and photovoltaic cells and between the photovoltaic cells and the black glass.

Although according to the foregoing description, the solar cell assembly of the subject invention has the foregoing structure, it is only for illustrative purposes and is not intended to limit the present invention.

Except for the black glass of the subject invention, the solar cell assembly may be prepared by any conventional methods.

### EXAMPLES

The black coatings prepared according to the embodiments of the subject invention have the following compositions.

| | Example 1 | Example 2 |
|---|---|---|
| Ingredients | (Mass percentage %) | (Mass percentage %) |
| Inorganic film- | 12% SiO₂ of a particle | 6% Al₂O3 of a particle |
| forming materials | size from about 0.5 | size of about 1 μm |
| | μm to about 2 μm | |
| | 3% BaSO₄ of a particle | 2% MgCO₃ |
| | size from about 0.5 | |
| | μm to about 2 μm | |
| | | 8% SiO₂ of a particle size |
| | | from about 0.5 μm to |
| | | about 2 μm |
| Black pigments | 8% carbon black | 3% carbon black |
| | | 7% carbon black |
| Adhesives | 8% γ-(3- | 10% tetraethyl |
| | Glycidyloxypro- | orthosilicate |
| | pyl)methoxysilane | |
| | 7% acrylate | 5% polyurethane |
| Auxiliaries | 5% dispersants | 3% thickening agents |
| | 2% light stabilizers | 4% anti-skinning agents |
| | 2% defoamers | 3% anti-settling agents |
| | | 2% abrasion resistants |
| | | 2% defoamers |
| catalysts | 0.5% HCl | 0.8% oxalic acid |
| solvents | 20% water | 16% water |
| | 20% ethanol | 24% isopropanol |
| | 12.5% isopropanol | 4.2% diethylamine |

### Example 1

The black coating is obtained by mixing the inorganic film-forming materials, pigments, adhesives, auxiliaries and solvents according to the ratios set forth above, at 30° C. for 6 hours; and stirring for 16 hours after the addition of catalysts.

### Example 2

The black coating is obtained by mixing the inorganic film-forming materials, pigments, adhesives, auxiliaries and solvents according to the ratios set forth above at 50° C. for 4 hours; and stirring for 16 hours after the addition of catalysts.

### Example 3

The black coating composition of Example 1 is applied onto a surface of the glass substrate by spray coating, and the coated glass substrate is baked at 200° C. for 20 minutes to obtain a black glass.

### Example 4

The black coating composition of Example 2 is applied onto a surface of the glass substrate by roll coating, and the coated glass substrate is baked at 300° C. for 15 minutes to obtain a black glass.

The black glass of the subject invention has better weather resistance due to the presence of a large amount of inorganic film-forming material. The black glass of the subject invention shows a color of black, and such black glass not only provides a solar cell assembly with various visual appearance options but also meets the requirements for long-term outdoor use and broadens the extent of the applications of a solar cell assembly.

The coating process used in the subject invention is simple and carried out at low cost, and thus is suitable for mass production.

It should be understood that the foregoing description and the appended drawing are given for illustration and reference only, without any intention to limit the scope of the present invention. The scope of the invention should only be limited by the appended claims. Various changes and modifications within the spirit and scope of the invention will become apparent to those skilled in the art from this detailed description.

What is claimed is:

1. A black glass comprising: a glass substrate; and a black coating formed on the glass substrate, wherein the black coating comprises an inorganic film-forming material, a black pigment and an adhesive.

2. The black glass according to claim 1, wherein based on the total weight of the black coating, the inorganic film-forming material has a content of about 3% to about 40%; the black pigment has a content of about 0.1% to about 20%; and the adhesive has a content of about 3% to about 40%.

3. The black glass according to claim 1, wherein the inorganic film-forming material is selected from the group consisting of SiO₂, ZrO₂, BaSO₄, Al₂O₃, CaCO₃, CaSO₄, ZnO, Pb₃O₄, Sb₂O₃, TiO₂, MgO, MgCO₃, mica, lead white, and talc.

4. The black glass according to claim 1, wherein the black pigment is selected from the group consisting of carbon black, lamp black, acetylene black, channel black, gas black, thermal black, graphite, bone black, iron oxide black, and nigrosin.

5. The black glass according to claim 1, wherein the inorganic film-forming material has a particle size of about 0.001 μm to about 50 μm.

6. The black glass according to claim 1, wherein the adhesive is selected from the group consisting of a colloid formed from alcoholates, organic salts, inorganic salts, and/or organometallic compounds, and organic polymers.

7. The black glass according to claim 1, wherein the black glass further comprises additives and solvents, wherein the additives are selected from the group consisting of catalysts, emulsifiers, dispersants, polymerization inhibitors, rheological agents, anti-settling agents, siccatives, anti-skinning agents, anti-shrinking agents, anti-impairment agents, anti-oxidation agents, lubricants, release agents, thermal stabilizers, light stabilizers, anti-electrostatic agents, abrasion resistants, thickening agents, and defoamers.

8. The black glass according to claim 1, wherein the glass substrate is a plate glass or a calendered glass.

9. The black glass according to claim 1, wherein the black coating has a thickness of about 0.2 μm to about 200 μm.

10. A solar cell assembly comprising:
a front glass substrate;
a black coating formed on the glass substrate to form a black glass, wherein the black coating comprises an inorganic film-forming material, a black pigment and an adhesive.; and
a photovoltaic cell positioned between the front glass substrate and the black glass.

11. A solar cell assembly according to claim 10, wherein based on the total weight of the black coating, the inorganic film-forming material has a content of about 3% to about 40%; the black pigment has a content of about 0.1% to about 20%; and the adhesive has a content of about 3% to about 40%.

12. A solar cell assembly according to claim 10, wherein the inorganic film-forming material is selected from the group consisting of SiO₂, ZrO₂, BaSO₄, Al₂O₃, CaCO₃,CaSO₄, ZnO, Pb₃O₄, Sb₂O₃, TiO₂, MgO, MgCO₃, mica, lead white, and talc:

13. A solar cell assembly according to claim 10, wherein the black pigment is selected from the group consisting of carbon black, lamp black, acetylene black, channel black, gas black, thermal black, graphite, bone black, iron oxide black, and nigrosine.

14. A solar cell assembly according to claim 10, wherein the inorganic film-forming material has a particle size of about 0.001 μm to about 50 μm.

15. A solar cell assembly according to claim 10, wherein the adhesive is selected from the group consisting of a colloid formed from alcoholates, organic salts, inorganic salts, and/or organometallic compounds, and organic polymers.

16. A solar cell assembly according to claim 10, wherein the black glass further comprises additives and solvents, wherein the additives are selected from the group consisting of catalysts, emulsifiers, dispersants, polymerization inhibitors, rheological agents, anti-settling agents, siccatives, anti-skinning agents, anti-shrinking agents, anti-impairment agents, anti-oxidation agents, lubricants, release agents, thermal stabilizers, light stabilizers, anti-electrostatic agents, abrasion resistants, thickening agents, and defoamers.

17. A solar cell assembly according to claim 10, wherein the glass substrate is a plate glass or a calendered glass.

18. A solar cell assembly according to claim 10, wherein the black coating has a thickness of about 0.2 μm to about 200 μm.

19. The black glass according to claim 1, wherein the inorganic film-forming material comprises material comprising any combination selected from the group consisting of SiO₂, ZrO₂, BaSO₄, Al₂O₃, CaCO₃, CaSO₄, ZnO, Pb₃O₄, Sb₂O₃, TiO₂, MgO, MgCO₃, mica, lead white, and talc.

20. The black glass according to claim 1, wherein the black glass further comprises any combination of additives selected from the group consisting of catalysts, emulsifiers, dispersants, polymerization inhibitors, rheological agents, anti-settling agents, siccatives, anti-skinning agents, anti-shrinking agents, anti-impairment agents, anti-oxidation agents, lubricants, release agents, thermal stabilizers, light stabilizers, anti-electrostatic agents, abrasion resistants, thickening agents, and defoamers.
